(19) United States
(12) Patent Application Publication
(10) Pub. No.: US 2012/0049027 A1
(43) Pub. Date: Mar. 1, 2012

(54) MOUNTING APPARATUS FOR EXPANSION CARD

(75) Inventor: LI-PING CHEN, Tu-Cheng (TW)

(73) Assignee: HON HAI PRECISION INDUSTRY CO., LTD., Tu-Cheng (TW)

(21) Appl. No.: 13/083,587

(22) Filed: Apr. 10, 2011

(30) Foreign Application Priority Data
Aug. 27, 2010 (CN) 201010264758.8

(51) Int. Cl. H05K 7/14

(52) U.S. Cl. 248/309.1

(57) ABSTRACT

A mounting apparatus includes a chassis including a rear plate and a mounting member, a through hole defined in the rear plate, a maintaining piece located on the rear plate at a first side of the through hole, and a securing portion located on the rear plate at a second side. The mounting member includes a connecting portion, a rotating portion, and a pressing plate. The rotating portion and the pressing plate extend from opposite edges of the connecting portion. The rotating portion is rotatably engaged with the securing portion, and the pressing plate is configured for securing an expansion card on the maintaining piece.

### REARGROUND

1. Technical Field

The present disclosure relates to mounting apparatuses, and particularly to a mounting apparatus for securing an expansion card to an electronic device.

2. Description of Related Art

A computer system usually includes electronic cards, which typically provide additional functions for the computer system and are commonly referred to as expansion cards, such as sound cards, video cards, and graphics cards, for enhancing the capabilities of the computer system. It is labor intensive and time-consuming to replace or upgrade the expansion cards as they are often attached to the computer system with screws.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric, cutaway view of a mounting apparatus and an expansion card in accordance with one embodiment.

FIG. 2 is an isometric view of a mounting member of FIG. 1.

FIG. 3 is an exploded view of a positioning member of FIG. 1.

FIG. 4 is similar to FIG. 1, but shows the mounting member and the positioning member secured to a chassis.

FIG. 5 is an assembled, cutaway view of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

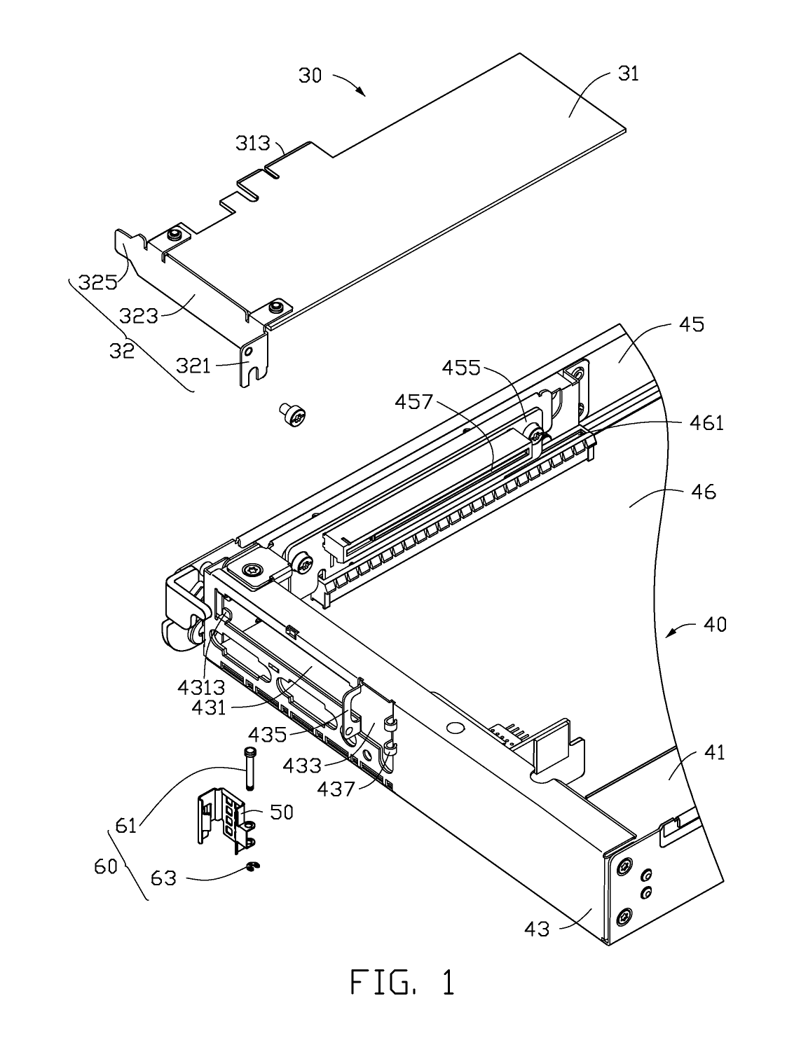

Referring to FIG. 1, according to one embodiment, the expansion card 30 includes a main body 31. A securing piece 32 mounted to the main body 31. The securing piece 32 includes a mounting portion 323, a maintaining portion 321 connected to the mounting portion 323, and an inserting portion 325. The inserting portion 325 extends from one end of the mounting portion 323 and is substantially perpendicular to the maintaining portion 321. The expansion card 30 may be, for example, a sound card, a video card, or other Peripheral Component Interconnect (PCI) Express (PCI-E), or small computer system interface (SCSI), etc.

The mounting apparatus, in accordance with one embodiment, includes a chassis 40, a mounting member 50, and a positioning member 60.

The chassis 40 includes a bottom plate 41, a rear plate 43 and a side plate 45. A main board 46 is attached to the bottom plate 41 and includes a first socket 461. The rear plate 43 defines an opening 431, in one embodiment, which extends in a direction substantially perpendicular to the side plate 45. A through hole 433, communicating with the opening 431, is defined in the rear plate 43 on the right side of the opening 431. Two positioning pieces 4313, adjacent the side plate 45, are located on the upper and lower edges of the opening 431. A maintaining piece 435 is connected to the upper and lower edges of the opening 431 and substantially perpendicular to the rear plate 43. Two securing portions 437, each with a pivot hole (not labeled), are located on the right edge of the through hole 433. A riser card 455 is engaged in the first socket 461 and secured to the side plate 45. A second socket 457 is located on the riser card 455 and configured for receiving the inserting portion 325 of the expansion card 30.

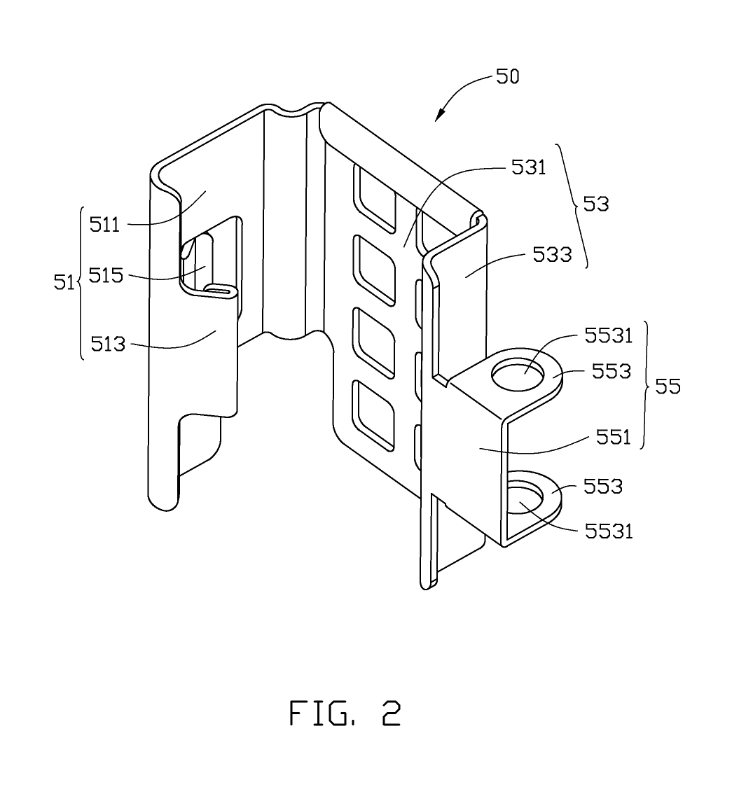

Referring to FIG. 2, the mounting member 50 includes a pressing portion 51, a rotating portion 55, and a connecting portion 53 connected to the pressing portion 51 and the rotating portion 55. The pressing portion 51 includes a pressing plate 511, an operating portion 513 and a resilient piece 515. The operating portion 513 can be elastically deformed and the resilient piece 515 is located on the pressing plate 511. The operating portion 513 extends from a side edge of the pressing plate 511. The connecting portion 53 includes a first connecting wall 531, connected to the pressing plate 511, and a second connecting wall 533, connected to the rotating portion 55. In accordance with an embodiment, the size of the first connecting wall 531 is substantially equal to that of the through hole 433. The rotating portion 55 includes a connecting piece 551 and two rotating pieces 553. The connecting piece 551 extends from an edge of the second connecting wall 533. The rotating pieces 553 are located on the upper and lower edges of the connecting piece 551. Each rotating pieces 553 defines a pivot hole 5531.

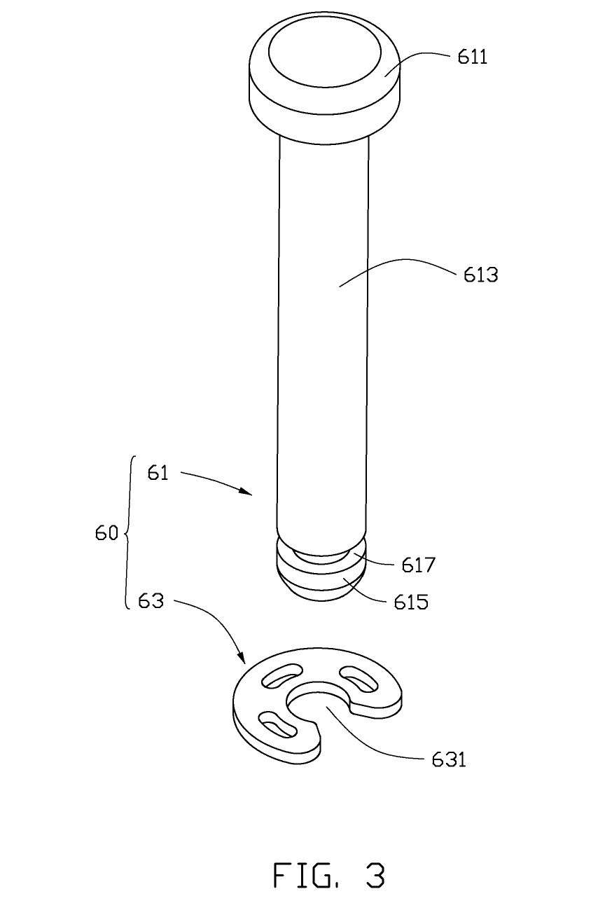

Referring to FIG. 3, the positioning member 60 includes a positioning post 61 and a clasp 63. The positioning post 61 includes a first positioning portion 611, a second positioning portion 613, and a third positioning portion 615. The second positioning portion 613 connects the first positioning portion 611 to the third positioning portion 615. A notch 617 is defined in the positioning member 60 between the second positioning portion 613 and the third positioning portion 615. The diameter of the first positioning portion 611 is greater than that of each of the second positioning portion 613, the third positioning portion 615, and the pivot hole 5531. The third positioning portion 615 can be inserted into the pivot holes of the two securing portions 437 and the pivot hole 5531 of the mounting member 50. The clasp 63 defines a cutout 631 and can be received in the notch 617. The outer diameter of the clasp 63 is greater than the diameter of each of the second positioning portion 613 and the third positioning portion 615. The diameter of the cutout 631 is smaller than that of each of the second positioning portion 613 and the third positioning portion 615.

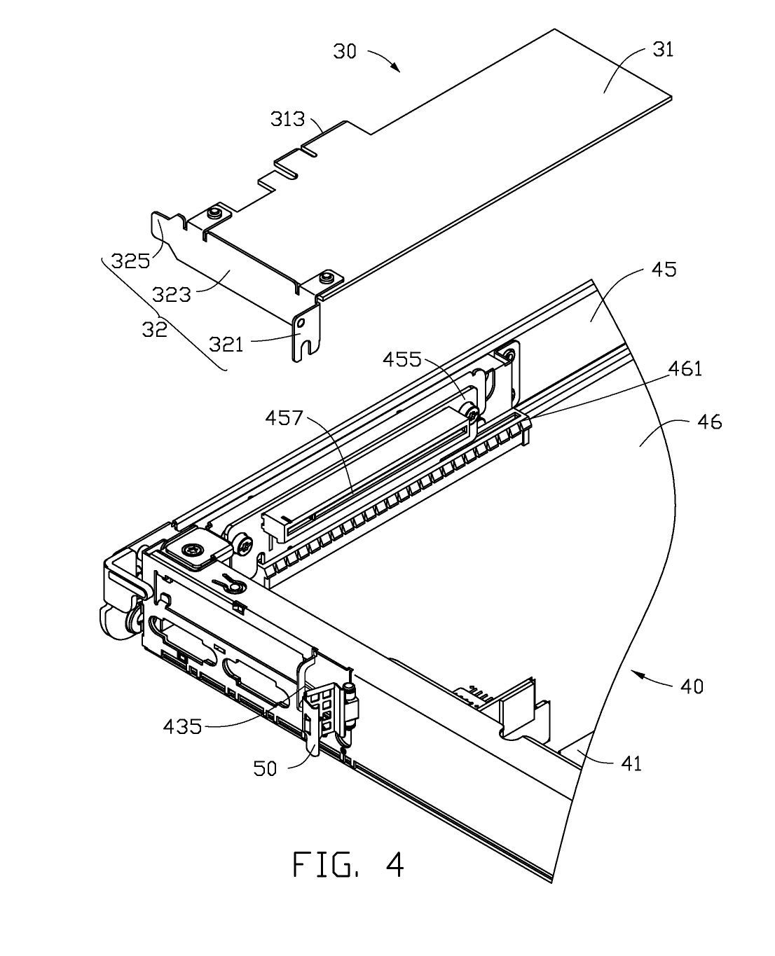

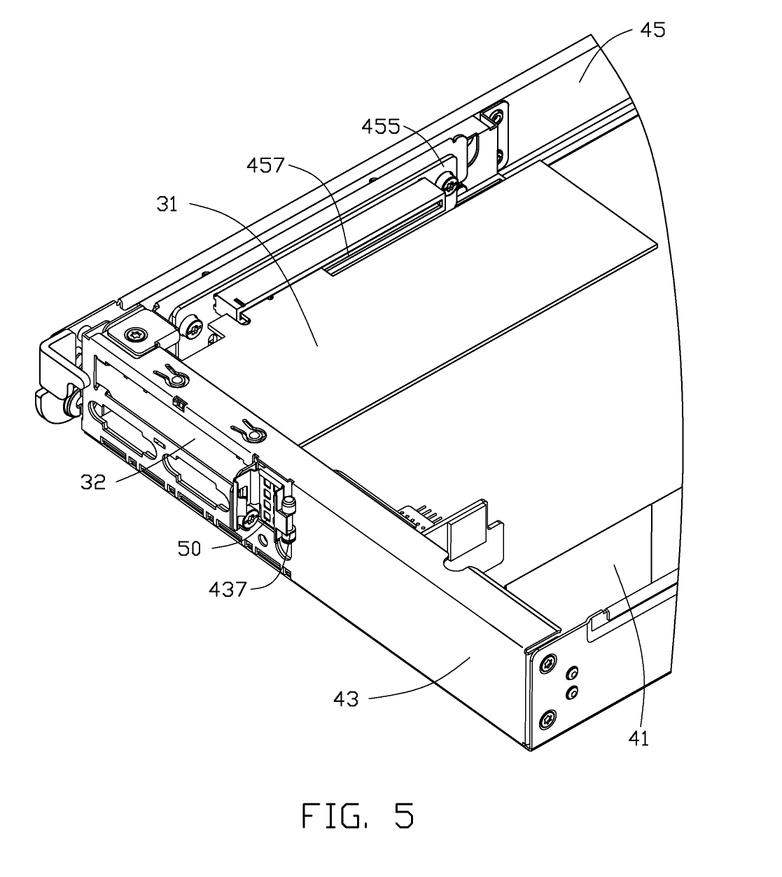

Referring to FIG. 4 and FIG. 5, in assembly of the mounting member 50 and the two rotating pieces 553 are placed between the two securing portions 437 of the rear plate 43. The two securing portions 437 are aligned with the pivot holes 5531 of the two rotating pieces 553. The second positioning portion 613 and the third positioning portion 615 are extended through the pivot holes of the securing portion 437 and the pivot holes 5531, until the first positioning portion 611 is blocked by the rotating piece 553. The clasp 63 is engaged in the notch 617, thereby securing the mounting member 50 to the rear plate 43.

In assembly of the expansion card 30, the inserting portion 325 of the expansion card 30 is inserted in the second socket 457 of the riser card 455. The maintaining portion 321 is engaged in the through hole 433 and located on the maintaining piece 435. The inserting portion 325 is located between the positioning pieces 4313 and the inner surface of the rear plate 43.

The mounting member 50 is rotated towards the maintaining piece 435, by driving the operating portion 513 until the pressing plate 511 is blocked by the maintaining portion 321 of the expansion card 30. The mounting member 50 is further pushed to cause the maintaining portion 321 to elastically deform the pressing plate 511 and the resilient piece 515, so that the mounting member 50 can further rotate until the first connecting wall 531 touches the rear plate 43. The pressing plate 511 and the resilient piece 515 are resiliently deformed and press the maintaining portion 321 of the expansion card 30. Therefore, the expansion card 30 is mounted to the chassis 40.

In disassembly, the pressing plate 511 is elastically deformed by driving the operating portion 513, until the resilient piece 515 and the pressing plate 511 are disengaged from the maintaining portion 321. Then, the mounting member 50 is rotated away from the maintaining portion 321. Thus, the expansion card 30 can be removed from the chassis 40.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. A mounting apparatus comprising:
a chassis comprising a rear plate, a through hole defined in the rear plate, a maintaining piece located on the rear plate at a first side of the through hole, and a securing portion located on the rear plate at a second side; and
a mounting member comprising a connecting portion, a rotating portion and a pressing plate; the rotating portion and the pressing plate extends from opposite edges of the connecting portion; the rotating portion is rotatably engaged with the securing portion; and the pressing plate configured for securing an expansion card on the maintaining piece.

2. The mounting apparatus of claim 1, wherein the pressing plate is deformable towards the rotating portion for disengaging from the expansion card.

3. The mounting apparatus of claim 1, wherein the mounting member comprises an operating portion configured for driving the mounting member rotate, and the operating portion extends from the pressing plate.

4. The mounting apparatus of claim 1, wherein a resilient piece is located on the pressing plate and configured for engaging a securing piece installed in the expansion card.

5. The mounting apparatus of claim 4, wherein the securing piece is located between the maintaining piece and the resilient piece.

6. The mounting apparatus of claim 1, wherein the rotating portion comprises a connecting piece and a rotating piece extending from the connecting piece; the rotating piece is rotatably engaged with the securing portion on the chassis; and an extending direction of the rotating piece is opposite to that of the pressing plate.

7. The mounting apparatus of claim 1, wherein the connecting portion comprises a first connecting wall, connected to the pressing plate, and a second connecting wall, connected to the rotating portion; and the first connecting wall is substantially perpendicular to the second connecting wall.

8. The mounting apparatus of claim 7, wherein the size of the first connecting wall is substantially equal to that of the through hole.

9. The mounting apparatus of claim 1, wherein the rear plate defines an opening in communication with the through hole; and the maintaining piece is connected to opposite edges of the opening and located between the through hole and the opening.

10. The mounting apparatus of claim 9, wherein the chassis further comprises a side plate substantially perpendicular to the rear plate; and the opening extends in a direction substantially perpendicular to the side plate.

11. The mounting apparatus of claim 10, wherein a positioning piece, adjacent the side plate, is located on an edge of the opening.

12. The mounting apparatus of claim 1, wherein the mounting member is located outside the chassis.

13. A mounting apparatus comprising:
a chassis comprising a rear plate, a through hole defined in the rear plate, a maintaining piece is located on a first side of the through hole, and a securing portion is located on a second side;
a securing piece configured for being secured to an expansion card; and
a mounting member comprising a connecting portion, a rotating portion and a pressing plate; the rotating portion and the pressing plate extends from opposite edges of the connecting portion; the rotating portion is rotatably engaged with the securing portion; the mounting member is rotatable between a locking position, where the pressing plate is elastically deformed and secures the securing piece on the maintaining piece, and an unlocking position, where the pressing plate disengages from the securing piece.

14. The mounting apparatus of claim 13, wherein the mounting member is rotatably mounted to the securing portion by a positioning member, and the positioning member is located in the securing portion.

15. The mounting apparatus of claim 14, wherein the positioning member comprise a positioning post, and the positioning post comprises a first positioning portion, a second positioning portion and a third positioning portion; and the cross sections of the first positioning portion, second positioning portion and the third positioning portion are rounded.

16. The mounting apparatus of claim 15, wherein a diameter of the first positioning portion is greater than that of the second positioning portion and the third positioning portion.

17. The mounting apparatus of claim 15, wherein the positioning member further comprise a clasp which is engaged in the positioning post.

18. The mounting apparatus of claim 17, wherein a notch is defined between the second positioning portion and the third positioning portion, the clasp defines a cutout to engage in the notch.

19. The mounting apparatus of claim 17, wherein the clasp is crescent shaped.
